(19) United States
(12) Patent Application Publication
(10) Pub. No.: US 2023/0010642 A1
(43) Pub. Date: Jan. 12, 2023

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventor: Yi TANG, Hefei City (CN)

(73) Assignee: CHANGXIN MEMORY TECHNOLOGIES, INC., Hefei City (CN)

(21) Appl. No.: 17/932,593

(22) Filed: Sep. 15, 2022

(30) Foreign Application Priority Data
Apr. 26, 2022 (CN) 202210450095.1

(51) Int. Cl. H01L 29/423; H01L 29/40; H01L 27/092; H01L 21/8234

(52) U.S. Cl. CPC H01L 29/42364; H01L 29/401; H01L 27/0922; H01L 21/823437

(57) ABSTRACT

A method for manufacturing a semiconductor structure includes: providing a substrate, at least a gate structure, a first dielectric layer covering a surface of the substrate and the gate structure being formed on the substrate, and a first dielectric layer on a side surface of the gate structure serving as a first sidewall; forming a sacrificial sidewall on a side surface of the first sidewall; removing the sacrificial sidewall after a first doped region and a second doped region are respectively formed in the substrate on both sides of the sacrificial sidewall; forming a second sidewall on a side surface of the first sidewall.

### CROSS-REFERENCE TO RELATED APPLICATION

The present application claims priority to Chinese Patent Application No. 202210450095.1 filed on Apr. 26, 2022, the disclosure of which is hereby incorporated by reference in its entirety.

### BACKGROUND

As integrated circuits and their devices continue to scale down, the dimensions of metal gate structures and contact structures between devices are also shrinking, resulting in an increase in the contact resistances between these metal gate structures or contact structures and the active areas.

### SUMMARY

The disclosure relates to the technical field of semiconductors, and relates to but is not limited to, a semiconductor structure and a method for manufacturing the same.

In a first aspect, embodiments of the disclosure provide a method for manufacturing a semiconductor structure. The method includes: providing a substrate, at least a gate structure, a first dielectric layer covering a surface of the substrate and covering the gate structure being provided on the substrate, a first dielectric layer on a side surface of the gate structure serving as a first sidewall; forming a sacrificial sidewall on a side surface of the first sidewall; removing the sacrificial sidewall after a first doped region and a second doped region are respectively formed in the substrate on both sides of the sacrificial sidewall; forming a second sidewall on the side surface of the first sidewall.

In a second aspect, embodiments of the disclosure provide a semiconductor structure. The semiconductor structure includes: a substrate; a gate structure, located on the substrate; a first dielectric layer covering a surface of the gate structure and part of a surface of the substrate, the first dielectric layer including a first sidewall located on a side surface of the gate structure; a second sidewall located at a side surface of the first sidewall; and a first doped region and a second doped region, respectively located on both sides of the second sidewall of the gate structure, and the first doped region and the second doped region respectively having a first distance from the second sidewall.

### BRIEF DESCRIPTION OF THE DRAWINGS

In the accompanying drawings (which may not be drawn to scale), the similar reference numerals may describe similar components in different views. The similar reference numerals with different letter suffixes may denote different examples of similar components. The drawings generally illustrate, by way of examples and not limitation, various embodiments discussed herein.

FIG. 1A is a flow chart of implementing a method for forming a semiconductor structure provided by an embodiment of the disclosure;

FIG. 1B is a structural schematic diagram in a process of forming a semiconductor structure provided by an embodiment of the disclosure;

FIG. 2A is a flow chart of implementing a method for forming a gate structure provided by an embodiment of the disclosure;

FIG. 2B is a first structural schematic diagram in a process for forming a semiconductor structure provided by embodiments of the disclosure;

FIG. 2C is a second structural schematic diagram in a process for forming a semiconductor structure provided by embodiments of the disclosure;

FIG. 2D is a third structural schematic diagram in a process for forming a semiconductor structure provided by embodiments of the disclosure;

FIG. 3A is a flow chart of implementing S106 in a method for forming a semiconductor structure provided by an embodiment of the disclosure;

FIG. 3B is a first structural schematic diagram of a process for forming a semiconductor structure provided by an embodiment of the disclosure;

FIG. 3C is a second structural schematic diagram of a process for forming a semiconductor structure provided by an embodiment of the disclosure;

FIG. 3D is a third structural schematic diagram of a process for forming a semiconductor structure provided by an embodiment of the disclosure;

FIG. 4A is a flow chart of implementing S108 in a method for forming a semiconductor structure provided by an embodiment of the disclosure;

FIG. 4B is a first structural schematic diagram in a process for forming a semiconductor structure provided by an embodiment of the disclosure;

FIG. 4C is a second structural schematic diagram in a process for forming a semiconductor structure provided by an embodiment of the disclosure;

FIG. 4D is a third structural schematic diagram in a process for forming a semiconductor structure provided by an embodiment of the disclosure;

FIG. 4E is a fourth structural schematic diagram in a process for forming a semiconductor structure provided by an embodiment of the disclosure;

FIG. 4F is a fifth structural schematic diagram in a process for forming a semiconductor structure provided by an embodiment of the disclosure;

FIG. 4G is a sixth structural schematic diagram in a process for forming a semiconductor structure provided by an embodiment of the disclosure;

FIG. 5A is a flow chart of implementing another method for forming a semiconductor structure provided by an embodiment of the disclosure;

FIG. 5B is a first structural schematic diagram in a process for forming a semiconductor structure provided by an embodiment of the disclosure;

FIG. 5C is a second structural schematic diagram in a process for forming a semiconductor structure provided by an embodiment of the disclosure;

FIG. 5D is a third structural schematic diagram in a process for forming a semiconductor structure provided by an embodiment of the disclosure;

FIG. 5E is a fourth structural schematic diagram in a process for forming a semiconductor structure provided by an embodiment of the disclosure; and

FIG. 5F is fifth a structural schematic diagram in a process for forming a semiconductor structure provided by an embodiment of the disclosure.

### DETAILED DESCRIPTION

Exemplary embodiments of the present disclosure will be described in more detail below with reference to the accompanying drawings. Although exemplary embodiments of the present disclosure are shown in the drawings, it should be understood that the present disclosure may be implemented in various forms and should not be limited to the specific embodiments set forth herein. These embodiments are provided so that the disclosure will be more thoroughly understood and the scope of the disclosure will be fully conveyed to those skilled in the art.

In the description hereinafter, numerous specific details are given to provide a more thorough understanding of the disclosure. However, it will be apparent to those skilled in the art that the disclosure may be implemented without one or more of these details. In other examples, some technical features well-known in the art are not described in order to avoid confusion with the present disclosure; that is, not all of the features of actual embodiments are described herein, and well-known functions and structures are not described in detail.

In the drawings, the dimensions of layers, regions, elements and their relative dimensions may be exaggerated for clarity. The same reference numeral denotes the same element throughout the text.

It should be understood that when an element or a layer is referred to as “on”, “adjacent to”, “connected to” or “coupled to” another element or layer, it may be directly on the other element or layer, adjacent to the other element or layer, or connected to or coupled to the other element or layer, or there may be an intermediate element or layer therebetween. In contrast, when an element is described as “directly on”, “directly adjacent to”, “directly connected to” or “directly coupled to” another element or layer, there is no intermediate element or layer therebetween. It should be understood that although the terms, “first”, “second”, “third” and the like may be used to describe various elements, components, regions, layers, and/or portions, these elements, parts, regions, layers, and/or portions should not be limited by these terms. These terms are only used to distinguish one element, part, region, layer or portion from another element, part, region, layer or portion. Therefore, without departing from the teaching of the present disclosure, a first element, part, region, layer or portion discussed hereinafter may be expressed as a second element, part, region, layer or portion. While discussing a second element, component, region, layer or portion, it does not imply that a first element, component, region, layer or portion is necessarily present in the present disclosure.

The terms used herein are intended to describe specific embodiments only and are not to be a limitation to the present disclosure. As used herein, the singular forms “a/an”, “one”, and “the/said” are intended to include the plural forms as well, unless the context clearly dictates otherwise. It should be further understood that when terms “consist of” and/or “comprise/include” used in the specification mean that the stated features, integers, steps, operations, elements and/or parts are present, but the presence or addition of one or more of other features, integers, steps, operations, elements, parts and/or groups is not excluded. When used herein, the term “and/or” includes any of the listed items and all combinations thereof.

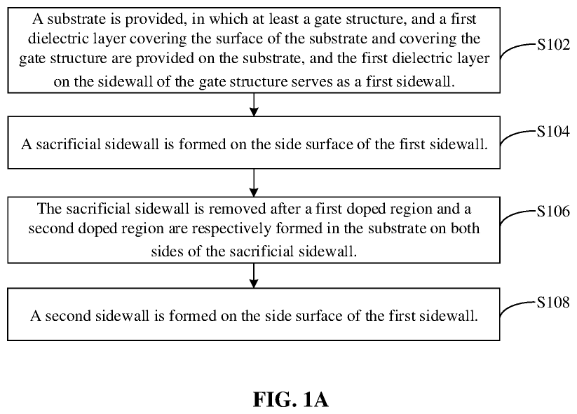

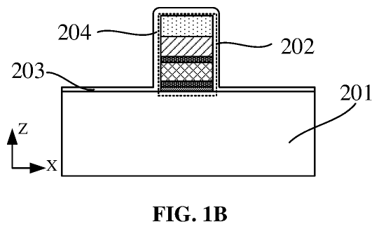

In view of this, the embodiments of the disclosure provide a method for manufacturing a semiconductor structure, referring to FIG. 1A, the method includes S102 to S108.

In S102, a substrate is provided, in which at least a gate structure, and a first dielectric layer covering the surface of the substrate and covering the gate structure are provided on the substrate, and the first dielectric layer on the sidewall of the gate structure serves as a first sidewall.

It could be understood that the substrate may include a top surface on the front and a bottom surface on the back opposite to the front; a direction perpendicular to the top and bottom surfaces of the substrate is defined as the third direction in the case of ignoring the flatness of the top and bottom surfaces. In the top surface and the bottom surface of the substrate (that is, the plane where the substrate is located), two directions intersecting each other (e.g. perpendicular to each other) are defined, for example, the extension direction of the gate structure may be defined as a second direction, and the arrangement direction of the first sidewall and the sacrificial sidewall may be defined as a first direction, and the plane of the substrate may be determined based on the first direction and the second direction. The first direction, the second direction and the third direction are perpendicular with each other. In the embodiments of the present disclosure, the first direction is defined as X-axis direction, the second direction is defined as Y-axis direction, and the third direction is defined as Z-axis direction.

Referring to FIG. 1B, a gate structure 202 and a first dielectric layer 203 are provided on the substrate 201. The extension direction of the gate structure 202 is the Y-axis direction (not shown), and the first dielectric layer 203 covers the surface of the substrate 201 and the gate structure 202. The first dielectric layer 203 on the side surfaces of the gate structure 202 serves as the first sidewall 204.

In embodiments of the disclosure, since the first dielectric layer can cover the surfaces of the gate structure and the substrate, in the subsequent ion implantation process, on the one hand, the first dielectric layer can block doping ions from entering the gate structure to a certain extent, on the other hand, the first dielectric layer can enhance the structural stability of the gate structure and reduce the stress effect in a subsequent process. Therefore, the gate structure on the substrate can be protected, thereby reducing the influence on the gate structure.

In some embodiments, the substrate may be a silicon substrate, a silicon-on-insulator substrate, or the like. The substrate may also include other semiconductor elements or semiconductor compounds, such as silicon carbide (SiC), gallium arsenide (GaAs), gallium phosphide (GaP), indium phosphide (InP), indium arsenide (InAs) or indium antimonide (InSb), or may include other semiconductor alloys such as gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenide photphide (GaInAsP) or combinations thereof.

In some embodiments, a shallow trench isolation (STI) structure may also be formed in the substrate, isolating a plurality of active areas within the substrate. The shallow trench isolation structure may be formed by forming a trench in the substrate and filling an isolation material layer in the trench. The material filling the shallow trench isolation structure may include silicon nitride, silicon oxide or the like, and silicon oxide may be formed by thermal oxidization. The shallow trench isolation structure can isolate a plurality of active areas in an array distribution or other distribution type in the substrate, and the active areas will be ion doped in the subsequent process to form source and drain regions for electrical connection with contact structures.

In some other embodiments, a local oxidation of silicon (LOCOS) isolation structure may be formed in the substrate. The process for forming the local oxidation of silicon isolation structure includes: firstly, depositing a silicon nitride layer on the surface of the substrate; then, etching part of the silicon nitride layer to expose part of the substrate, and oxidizing the exposed part of the substrate to generate local silicon oxide. Finally, active devices can be formed in the substrate covered by the silicon nitride layer. In this way, different active devices are isolated by local silicon oxide. Compared with the shallow trench isolation structure, local silicon oxide for isolation in the local oxidation of silicon isolation structure has a larger thickness and better isolation effect.

In some embodiments, the first dielectric layer may include one of or any combination of silicon nitride, silicon oxynitride, silicon carbonitride. During implementation, the first dielectric layer 203 may be a single-layer structure including a silicon nitride layer as shown in FIG. 1B. The first dielectric layer provided by the embodiments of the disclosure may also be a multi-layer structure, for example, the first dielectric layer includes a silicon nitride layer, a silicon oxynitride layer, and a silicon carbonitride layer.

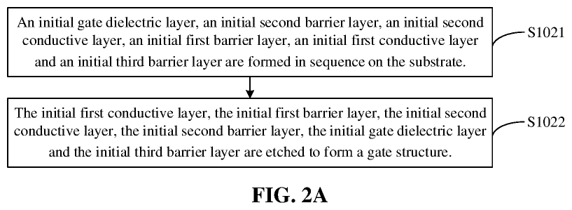

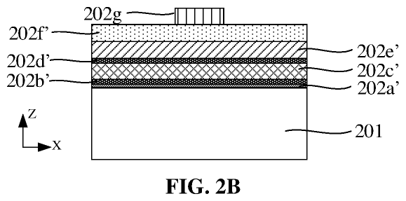

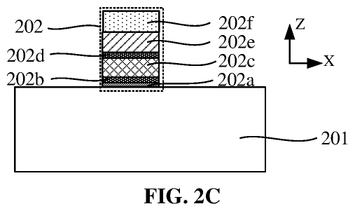

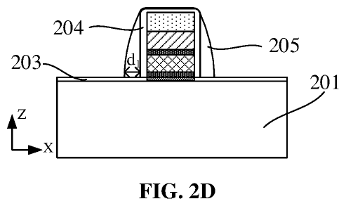

In some embodiments, the operations for forming the gate structure is shown in FIG. 2A, and may include S1021 and S1022. The operations for forming the gate structure will be described below with reference to FIG. 2B and FIG. 2C.

In S1021, an initial gate dielectric layer, an initial second barrier layer, an initial second conductive layer, an initial first barrier layer, an initial first conductive layer and an initial third barrier layer are formed in sequence on the substrate.

Referring to FIG. 2B, an initial gate dielectric layer 202a′, an initial second barrier layer 202b′, an initial second conductive layer 202c′, an initial first barrier layer 202d′, an initial first conductive layer 202e′ and an initial third barrier layer 202f′ are formed in sequence on the substrate 201.

In some embodiments, the initial gate dielectric layer may be a high-K material layer (e.g., having a dielectric constant greater than 3.9), such as may be one of or any combination of lanthanum oxide (La₂O₃), alumina (Al₂O₃), hafnium oxide (HfO₂), hafnium oxynitride (HfON), hafnium silicate (HfSiOx) or zirconia (ZrO₂). In this way, using a high-K material layer as the gate dielectric layer, it is possible to reduce the situation that electrons in the substrate pass through the gate dielectric layer and enter into the gate structure in the form of quantum, resulting in the leakage current of the gate structure. In other words, the quantum tunneling effect in the gate dielectric layer can be reduced, thereby reducing the leakage current of the gate structure and the power consumption caused by it.

The initial first conductive layer includes metal material, including one or more of tungsten, copper, aluminum, titanium, titanium nitride and tantalum, and the material of the initial second conductive layer is polysilicon.

During implementation, the initial third barrier layer may be formed by chemical vapor deposition, low temperature chemical vapor deposition, low pressure chemical vapor deposition, spin coating process, coating process, or the like. The material employed for the initial third barrier layer may be other suitable materials, such as silicon nitride, silicon oxynitride, or the like.

In some embodiments, the initial first barrier layer includes a barrier material doped with silicon. Herein, the barrier material may include one or more of titanium nitride, tantalum nitride, tungsten nitride, copper nitride and aluminum nitride. The initial first barrier layer is amorphized by doping the barrier material with silicon to change the crystalline state of the barrier material. Taking titanium nitride (TiN) as an example, pure titanium nitride thin film has a face-centered cubic (FCC) structure, which has a face preferred orientation with low surface energy. The crystal orientation of silicon-doped titanium nitride (TiSiN) also has a FCC structure that has a surface preferred orientation with low surface energy. When a part of Ti element in TiN is replaced by Si element, TiN will be amorphized and its blocking ability will be enhanced since the radius of Si is smaller than that of Ti.

In S1022, the initial first conductive layer, the initial first barrier layer, the initial second conductive layer, the initial second barrier layer, the initial gate dielectric layer and the initial third barrier layer are etched to form a gate structure.

Referring to FIG. 2B, a patterned photoresist 202g is formed by photolithography and the photoresist 202g may define a region for forming the gate structure. Referring simultaneously to FIG. 2B and FIG. 2C, with the photoresist 202g as a mask, the initial first conductive layer 202e′, the initial first barrier layer 202d′, the initial second conductive layer 202c′, the initial second barrier layer 202b′, and the initial gate dielectric layer 202a′, and the initial third barrier layer 202f′ outside the region for forming the gate structure are sequentially etched downward, and the initial gate dielectric layer 202a′, the initial second barrier layer 202b′, the initial second conductive layer 202c′, the initial first barrier layer 202d′, the initial first conductive layer 202e′, and the initial third barrier layer 202f′ located in the region for forming the gate structure are retained to form a gate structure 202. The gate structure 202 formed finally includes the gate dielectric layer 202a, the second barrier layer 202b, the second conductive layer 202c, the first barrier layer 202d, the first conductive layer 202e and the third barrier layer 202f are arranged sequentially from bottom to top.

In the embodiments of the disclosure, by arranging the first barrier layer, the second conductive layer and the second barrier layer between the gate dielectric layer and the first conductive layer, the distance between the gate dielectric layer and the first conductive layer can be increased, thereby reducing the situation that a voltage is applied to the gate dielectric layer and the gate dielectric layer is broken down due to the fact that the first conductive layer and the gate dielectric layer are too close together.

During implementation, the gate structure can be formed by a dry method (e.g., a plasma etching process, reactive ion etching process, or ion beam milling process). Gas used for dry etching may be one of trifluoromethane (CHF₃), carbon tetrafluoride (CF₄), difluoromethane (CH₂F₂), hydrobromic acid (HBr), chlorine (Cl₂) or sulfur hexafluoride (SF₆), or a combination thereof.

In embodiments of the disclosure, the gate dielectric layer may be hafnium dioxide layer, the second barrier layer may be titanium nitride layer, the second conductive layer may be polysilicon layer, the first barrier layer may be titanium nitride layer doped with silicon, the first conductive layer may be tungsten layer, and the third barrier layer may be silicon nitride. In this way, since the polysilicon layer can block tungsten, when tungsten atoms in the first conductive layer pass through the first barrier layer, the polysilicon layer acts as a barrier layer to block tungsten atoms from passing through, thereby reducing gate leakage. In addition, because polysilicon has good conformality, the second conductive layer using polysilicon also has good conformability.

In some embodiments, the thickness of the first dielectric layer is 5% to 20% of the thickness of the third barrier layer. In this way, since the thickness of the first dielectric layer is 5% to 20% of the thickness of the third barrier layer, that is, the thickness of the third barrier layer is greater than the first dielectric layer and the third barrier layer is sufficiently thick, the third barrier layer can prevent doping ions passing through the first dielectric layer. Therefore, during the third doped region is subsequently formed on the substrate, ions will not be doped in the gate structure, so that the gate structure will not be affected. In addition, referring to FIG. 1B, the substrate 201 is covered with the first dielectric layer 203, so that the stress of the substrate during ion doping can be improved and the stability of the device can be improved.

In S104, a sacrificial sidewall is formed on the side surface of the first sidewall.

Referring to FIG. 2D, a sacrificial sidewall 205 is formed on a side surface of the first sidewall 204.

During implementation, the sacrificial sidewall may be formed by depositing a silicon dioxide layer, an α-carbon layer, silicon oxynitride (SiON), a spin on hardmask (SOH) layer or a spin on carbon (SOC) layer on the substrate on which the first sidewall is formed, and then by dry etching. The dimension d₁ of the sacrificial sidewall in the first direction is the thickness of the sacrificial sidewall, and d₁ is 100 to 300 angstroms (Å).

In S106, the sacrificial sidewall is removed after a first doped region and a second doped region are respectively formed in the substrate on both sides of the sacrificial sidewall.

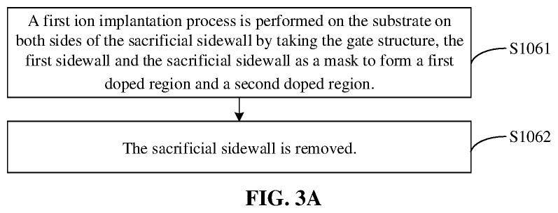

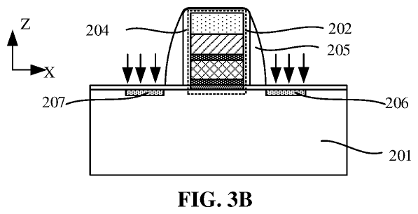

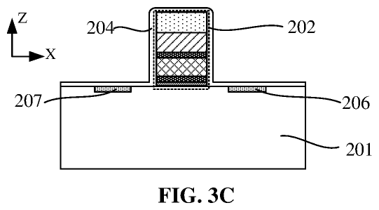

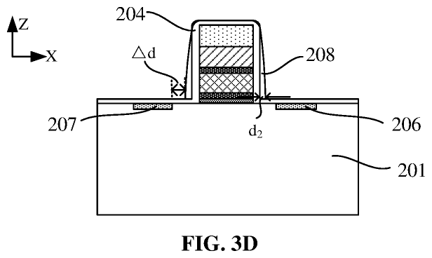

In some embodiments, referring to FIG. 3A, S106 may be implemented by S1061 and S1062.

In S1061, a first ion implantation process is performed on the substrate on both sides of the sacrificial sidewall by taking the gate structure, the first sidewall and the sacrificial sidewall as a mask to form a first doped region and a second doped region.

Here, the formation of the first doped region and the second doped region can be understood as the formation of a source and a drain, i.e., the formation of a source and drain regions.

Referring to FIG. 3B, the first ion implantation process is performed on the substrate 201 on both sides of the sacrificial sidewall 205 taking the gate structure 202, the first sidewall 204 and the sacrificial sidewall 205 as a mask to form a first doped region 206 and a second doped region 207. In order to reduce the feature size of the device, the doping depth of the first doped region and the second doped region needs to be correspondingly reduced, so as to reduce the short channel effect caused by the doping depth of the first doped region or the second doped region being too deep, thereby improving the reliability of the device.

The doping types of the first doped region and the second doped region may be the same, for example, both of them are N-type doping, or both of them are P-type doping. Of course, the doping types of the first doped region and the second doped region may be different, for example, one doped region is P-type doping and the other doped region is N-type doping. During implementation, the first ion corresponding to N-type doping may be ions of group VA, such as phosphorus, arsenic and antimony. The first ion corresponding to P-type doping can be ions of group IIIA, such boron or indium.

In some embodiments, the first ion implantation may be accomplished by processes such as thermal diffusion and plasma doping. The energy and dose used in the first ion implantation and the type of ions to be implanted may be determined according to the electrical properties of the semiconductor device to be formed.

The first ion implantation can be completed in one operation or divided into multiple operations. In multiple operation implantation, with the increase of the number of operations, the energy of the implanted first ion can gradually increase, while the implanted dose can gradually decrease.

During implementation, the implanted energy may be from 10 KeV to 200 KeV when the first ion (such as arsenic) implementation is performed by, for example plasma doping process. The junction depth of the first doped region and the second doped region finally formed is 30 to 100 nm. After ion implantation, a high-temperature annealing process may also be included. On the one hand, it can activate impurity ions in the first doped region and the second doped region to redistribute impurity ions. On the other hand, it can repair lattice damage caused by ion implantation.

In S1062, the sacrificial sidewall is removed.

Referring to FIG. 3B, the sacrificial sidewall 205 is removed by etching, such that the side surface of the first sidewall 204 can be exposed as shown in FIG. 3C.

As can be seen in conjunction with FIG. 2D, FIG. 3B and FIG. 3C, the purpose of forming the sacrificial sidewall 205 is to maintain the positions of the first doped region 206 and the second doped region 207, that is, the original positions of the first doped region 206 and the second doped region 207 do not change.

In S108, a second sidewall is formed on the side surface of the first sidewall.

Referring to FIG. 3D, a second sidewall 208 is formed on the side surface of the first sidewall 204. The dimension d₂ of the second sidewall 208 in the X-axis direction, is the thickness of the second side wall 208, d₂ may be 50 to 80 nm during implementation.

It should be noted that, the sacrificial sidewall and the second sidewall may be formed without a mask. In some embodiments, it may be formed in two operations.

In the first operation, a second sidewall material is deposited on the first dielectric layer 203; and the second sidewall material includes a single layer or a multilayer stack. In some embodiments, the second sidewall material includes a structure of oxide/nitride/oxide or nitride/oxide/nitride.

In the second operation, the second sidewall material on the surface of the first dielectric layer 203 on the substrate 201 and the surface of the first dielectric layer 203 on the top of the gate structure 202 is removed by etching, and the second sidewall material finally remaining on the side surface of the gate structure 202 forms the second sidewall 208.

In the embodiments of the disclosure, firstly, a sacrificial sidewall is formed on the side surface of the first sidewall, which can reduce the influence of the thickness of the sidewall structure on the positions of the source and drain regions. Secondly, after the sacrificial sidewall is removed, a second sidewall is formed on the sidewall of the first sidewall. The first sidewall and the second sidewall can not only reduce parasitic capacitance, but also reduce the leakage in the contact channels between the gate and the source and drain regions; finally, compared with the current semiconductor structure, the semiconductor structure formed by the method for manufacturing a semiconductor structure in the embodiments of the present disclosure can reduce the thickness of the second sidewall, and increase the distance between two adjacent second sidewalls, that is, increase the contact areas between the contact structures and the source and drain regions, thereby increasing the size of the contact structure, further reducing the contact resistance and achieving the effect of improving the device performance.

In some embodiments, the dimension of the sacrificial sidewall in the first direction (X-axis direction) is greater than the dimension of the second sidewall in the first direction, in which the first direction is the arrangement direction of the first sidewall and the sacrificial sidewall, and the first direction is parallel to the surface of the substrate. During implementation, the maximum dimension of the second sidewall in the X-axis direction is 15% to 80% of the maximum dimension of the sacrificial sidewall.

In some embodiments, the second sidewall includes a first sub-sidewall and a second sub-sidewall; referring to FIG. 3A, S108 may be implemented by S1081 and S1082.

In S1081, an initial first insulating layer covering the first dielectric layer is formed, part of the initial first insulating layer is removed, and the initial first insulating layer located on the side surface of the first sidewall is retained to form a first sub-sidewall.

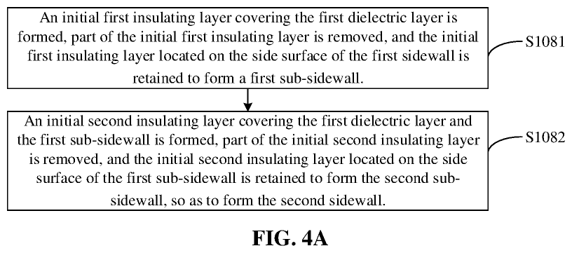

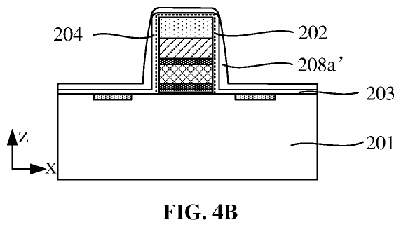

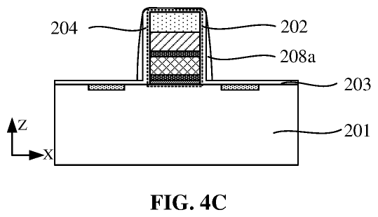

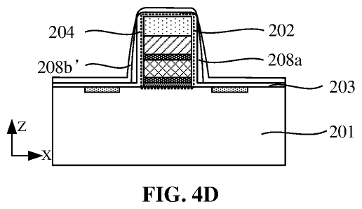

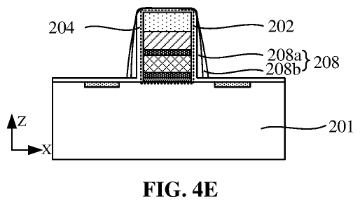

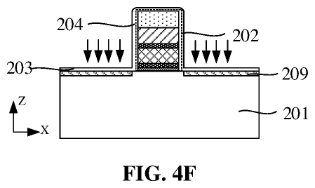

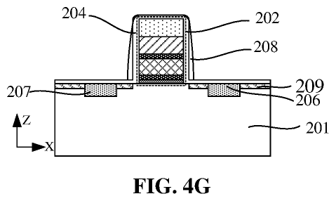

Referring to FIG. 4B, an initial first insulating layer 208a′ covering the first dielectric layer 203 is formed by chemical vapor deposition, low temperature chemical vapor deposition, low pressure chemical vapor deposition, spin coating, coating or the like. Referring to FIG. 4C, part of the initial first insulating layer 208a′ is removed by etching and the initial first insulating layer 208a′ located on the side surface of the first sidewall 204 is retained, that is, the initial first insulating layer 208a′ located on the top of the gate structure 202 and the initial first insulating layer 208a′ located on the surface of the substrate 201 are removed, forming a first sub-sidewall 208a as shown in 4C.

In S1082, an initial second insulating layer covering the first dielectric layer and the first sub-sidewall is formed, part of the initial second insulating layer is removed, and the initial second insulating layer located on the side surface of the first sub-sidewall is retained to form the second sub-sidewall, so as to form the second sidewall.

Referring to FIG. 4D, an initial second insulating layer 208b′ covering the first dielectric layer 203 and the first sub-sidewall 208a is formed by chemical vapor deposition, low temperature chemical vapor deposition, low pressure chemical vapor deposition, spin coating, coating or the like. Referring to FIG. 4E, part of the initial second insulating layer 208b′ is removed by etching, and the initial second insulating layer 208b′ located on the side surface of the first sub-sidewall 208a is retained to form a second sub-sidewall 208b, so as to form a second sidewall 208. The second sidewall 208 includes the first sub-sidewall 208a and the second sub-sidewall 208b.

In some embodiments, the structure of the first sub-sidewall and/or the second sub-sidewall may be flexibly arranged as needed, so as to achieve the effect of reducing parasitic capacitance. During implementation, it is required only that the total thickness of the final second sidewall is 50 nm to 80 nm. For example, referring to FIG. 4E, both the first sub-sidewall 208a and the second sub-sidewall 208b are single-layer structure, the constituent material of which may be silicon nitride.

For example, the first sub-sidewall and the second sub-sidewall may be a multilayer structure, for example, a nitride-oxide-nitride (N—O—N) stacked structure, a nitride-airgap-nitride (N-A-N) stacked structure, an ONO stacked structure, or the like. The first sub-sidewall and the second sub-sidewall may both include an ONO stacked structure; Of course, the first sub-sidewall and the second sub-sidewall may both include a NON stacked structure.

For another example, the first sub-sidewall may be a single-layer structure and the second sub-sidewall may be a stacked structure; Of course, the first sub-sidewall may be a stacked structure, and the second sub-sidewall may be a single-layer structure.

In some embodiments, before S104, the method further includes an operation S10.

In S103, third doped regions are formed in the substrate on both sides of the first sidewall. Here, the formation of the third doped regions has an effect of releasing the stress of the first dielectric layer.

In some embodiments, S103 may be implemented by S1031.

In S1031, a second ion implantation process is performed on the substrate on both sides of the first sidewall taking the first sidewall and the gate structure as a mask to form the third doped regions.

The second ion may be ions of ions of group VA, such as phosphorus, arsenic, antimony and the like, also may be ions of ions of group IIIA, such as boron, indium and the like. The doping type of the third doped region may be the same as or different from the doping types of the first doped region and the second doped region; the processes of ion doping can be the same or different. The third doped region may be a lightly doped drain (LDD) structure.

It could be understood that, the second ion implantation may be implemented by the same implantation process as the first ion implantation, or may be implemented by a different implantation process from the first ion implantation process. For example, the second ion implantation process may be plasma doping process, and the implantation energy of the second ion implantation may be 2 KeV to 120 KeV, and a junction depth of the third doped region finally formed is 5 nm to 50 nm.

Referring to FIG. 4F, a second ion implantation is performed on the substrate 201 on both sides of the first sidewall 204 taking the first sidewall 204 and the gate structure 202 as a mask to form third doped regions 209.

After the third doped regions are formed, a sacrificial sidewall is formed on a side surface of the first sidewall. The sacrificial sidewall is removed after a first doped region and a second doped region are respectively formed in the substrate on both sides of the sacrificial sidewall. Finally, the second sidewall as shown in FIG. 4G is formed on the side surface of the first sidewall.

In the embodiments of the disclosure, third doped regions are formed by an ion implantation process, impurity concentration gradients can be formed between the source and drain regions and the channels, thereby reducing the peak electric field near the drain, so as to improve the reliability of the device.

In some embodiments, at least a first gate structure and a second gate structure which are adjacent are provided on the substrate, a first doped region is formed between the first gate structure and the second gate structure, and second doped regions are formed on both sides of the first gate structure and the second gate structure respectively. In this way, the first gate structure and the second gate structure can share the first doped region, thereby increasing the density of the device and further improving the integration of the device.

The embodiments of the disclosure provide a semiconductor structure, referring to FIG. 3D, the semiconductor structure includes: a substrate 201; a gate structure 202 located on a substrate 201; a first dielectric layer 203, in which the first dielectric layer 203 covers the surface of the gate structure 202 and part of the surface of the substrate 201, the first dielectric layer 203 includes a first side surface 204 which is located on the sidewall of the gate structure 202; a second sidewall 208 located on the side surface of the first sidewall 204; and a first doped region 206 and a second doped region 207, in which the first doped region 206 and the second doped region 207 are respectively located on both sides of the second sidewall 208 of the gate structure 202, and the first doped region 206 and the second doped region 207 having a first distance Ad from the second sidewall.

It could be understood that, the first doped region and the second doped region is formed by performing a first ion implantation process on the substrate on both sides of the sacrificial sidewall taking the gate structure, the first sidewall and the sacrificial sidewall as a mask, that is, the first doped region and the second doped region are located in the substrate on both sides of the sacrificial sidewall. At the same time, since the thickness of the sacrificial sidewall is greater than the thickness of the second sidewall, after the sacrificial sidewall is removed and the second sidewall is formed, the first doped region and the second doped region have a first distance Δd from the second sidewall. The first distance Δd can be understood as the difference between the thickness d₁ of the sacrificial sidewall and the thickness d₂ of the second sidewall.

In the semiconductor structure provided by the embodiment of the disclosure, the first doped region and the second doped region have a first distance with the second sidewall, so that the contact area between the contact structure and the active area can be increased, and thus the contact resistance can be reduced without destroying the metal-oxide semiconductor field effect transistor (MOSFET) structure.

In some embodiments, the first dielectric layer includes one of or any combination of silicon nitride, silicon oxynitride, silicon carbonitride.

In some embodiments, referring to FIG. 4G, the semiconductor structure further includes third doped regions 209 which are located in the substrate 201 on both sides of the first sidewall 204 and partially overlap the second sidewall 208. The third doped regions can form impurity concentration gradients between the source and drain regions and the channels, thereby reducing the peak electric field near the drain, so as to improve the reliability of the device.

In some embodiments, referring to FIG. 2C, the gate structure 202 includes a third barrier layer 202f, a first conductive layer 202e, a first barrier layer 202d, a second conductive layer 202c, a second barrier layer 202b and a gate dielectric layer 202a arranged in sequence from top to bottom.

In some embodiments, the gate dielectric layer may include a high-K material layer. By using the high-K material layer as the gate dielectric layer, it is possible to reduce the situation that electrons in the substrate pass through the gate dielectric layer and enter into the gate structure in the form of quantum, resulting in the leakage current of the gate structure. In other words, the quantum tunneling effect in the gate dielectric layer can be reduced, thereby reducing the leakage current of the gate structure and the power consumption caused by it.

In some embodiments, the first barrier layer may include a barrier material layer doped with silicon. Compared with the barrier material layer undoped with silicon, the barrier material layer is amorphized after doped with silicon, thereby enhancing the barrier capability; the first conductive layer may include a metal material, and the second conductive layer may include polysilicon. After the metal in the first conductive layer passes through the first barrier layer, the polysilicon layer acts as a barrier layer to block metal from passing through, thereby reducing gate leakage. In addition, because polysilicon has good conformality, the second conductive layer using polysilicon also has good conformality.

In some embodiments, the thickness of the first dielectric layer is 5% to 20% of the thickness of the third barrier layer 202f. Since the thickness of the third barrier layer is greater than the first dielectric layer and the third barrier layer is sufficiently thick, the third barrier layer can block doping ions which passed through the first dielectric layer. Therefore, when the third doped regions are subsequently formed on the substrate, ions will not be doped in the gate structure, so that the gate structure will not be affected.

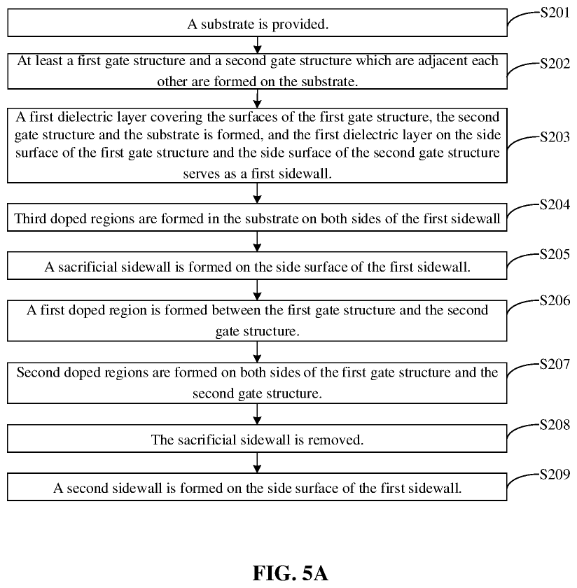

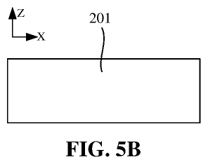

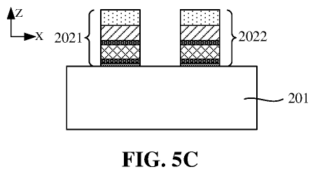

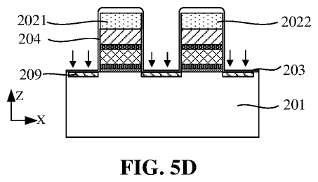

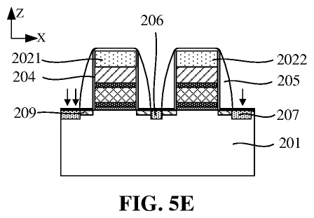

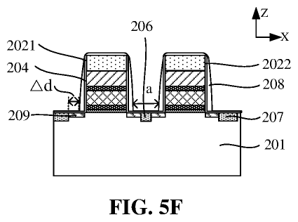

The embodiments of the disclosure further provide a method for forming a semiconductor structure, referring to FIG. 5A, including S201 to S209.

In S201, a substrate is provided.

Referring to FIG. 5B, a substrate 201 is provided. During implementation, the substrate may include a P-well and an N-well. Subsequently, an N-metal-oxide-semiconductor (NMOS) is formed in the P-well and a P-metal-oxide-semiconductor (PMOS) is formed in the N-well, and further a complementary metal oxide semiconductor (CMOS) is formed.

In S202, at least a first gate structure and a second gate structure which are adjacent with each other are formed on the substrate.

Referring to FIG. 5C, at least a first gate structure 2021 and a second gate structure 2022 which are adjacent are formed on the substrate 201.

During implementation, the first gate structure and the second gate structure may be the same or different. For example, the first gate structure and the second gate structure may include a third barrier layer, a first conductive layer, a first barrier layer, a second conductive layer, a second barrier layer and a gate dielectric layer arranged in sequence from top to bottom. Embodiments of the disclosure do not limit the first gate structure and the second gate structure. The first gate structure and the second gate structure may be formed on a P-well and an N-well, respectively. The first gate structure may control the turn-off or turn-on of an NMOS device, and the second gate structure may control the turn-off or turn-on of a PMOS device.

In S203, a first dielectric layer covering the surfaces of the first gate structure, the second gate structure and the substrate is formed, and the first dielectric layer on the side surface of the first gate structure and the side surface of the second gate structure serves as a first sidewall.

In S204, third doped regions are formed in the substrate on both sides of the first sidewall.

Here, the formation of third doped regions may be the formation of lightly doped drain (LDD) structure. S203 and S204 are described below with reference to FIG. 5D. A first dielectric layer 203 covering the surfaces of the first gate structure 2021, the second gate structure 2022 and the substrate 201 is formed, and the first dielectric layer 203 on the side surface of the first gate structure 2021 and the side surface of the second gate structure 2022 serves as a first sidewall 204. Third doped regions 209 are formed in the substrate 201 on both sides of the first sidewall 204.

In S205, a sacrificial sidewall is formed on the side surface of the first sidewall.

In S206, a first doped region is formed between the first gate structure and the second gate structure.

In S207, second doped regions are formed on both sides of the first gate structure and the second gate structure.

It can be understood that assuming that the first gate structure and the second gate structure are formed on a P-well and an N-well respectively, the first doped region is the active area in the NMOS and meanwhile is also the active area in contact with the P-well, so that the doping ions in the first doped region may be ions of group VA such as phosphorus, arsenic, antimony, or the like. The second doped region is the active area in the PMOS and meanwhile is also the active area in contact with the N-well, so that the doping ions in the second doped region may be ions of group IIIA such as boron, indium, or the like.

During implementation, S206 and S207 may be executed simultaneously, or S207 may be executed firstly and then S206 is executed, or S206 may be executed firstly and then S207 is executed, which is not limited in the embodiment of the disclosure. S205 to S207 are described below with reference to FIG. 5E. A sacrificial sidewall 205 is formed on a side surface of the first sidewall 204. A first doped region 206 is formed between the first gate structure 2021 and the second gate structure 2022 by plasma doping. Second doped regions 207 are formed on both sides of the first gate structure 2021 and the second gate structure 2022 by plasma doping.

In S208, the sacrificial sidewall is removed.

In S209, a second sidewall is formed on the side surface of the first sidewall.

Referring to FIG. 5F, the sacrificial sidewall 205 is removed by etching and a second sidewall 208 is formed on the side surface of the first sidewall 204.

The embodiments of the disclosure provide a semiconductor structure, referring to FIG. 5F, the semiconductor structure includes: a substrate 201; a first gate structure 2021 and a second gate structure 2022 located on the substrate 201; a first dielectric layer 203 covering the surfaces of the first gate structure 2021 and the second gate structure 2022 and the surface of part of the substrate 201, in which the first dielectric layer 203 includes a first sidewall 204 that is located on the side surfaces of the first gate structure 2021 and the second gate structure 2022; a first doped region 206 and second doped regions 207, in which the first doped region 206 is located between the first gate structure 2021 and the second gate structure 2022, and the second doped regions 207 are located on both sides of the first gate structure 2021 and the second gate structure 2022, respectively; and a second side wall 208 located on the side surface of the first sidewall 204, in which the first doped region 206 and the second doped region 207 have a first distance Ad from the second sidewall 208.

In the semiconductor structure provided by the embodiment of the disclosure, the distance a between the second sidewall on the right side of the first gate structure and the second sidewall on the left side of the second gate structure is relatively large, so that the size of the contact structure can be enlarged, and further the contact resistance between the contact structure and the active area can be reduced.

In several embodiments provided by the present disclosure, it should be understood that the disclosed apparatus and method may be implemented in a non-targeted manner. The device embodiments described above are only illustrative, for example, the division of units is only a logical function division. In actual implementation, there may be other division methods, for example, multiple units or assemblies may be combined, or integrated into another system, or some features may be ignored or not implemented. In addition, the constituent parts shown or discussed are coupled or directly coupled with each other.

The units described above as separate components may or may not be physically separated, and the components displayed as a unit may or may not be a physical unit, i.e., it may be located in one place or may be distributed on multiple network units. Part or all of the units can be selected according to actual requirements to achieve the purpose of the embodiment solution.

The features disclosed in the several method embodiments or device embodiments provided in the disclosure can be arbitrarily combined as long as there is no conflict therebetween to obtain a new embodiment of a method or a device.

The descriptions above are only some implementations of the embodiments of the present disclosure, and are not intended to limit the protection scope of the embodiments of the present disclosure. Any change and replacement may be easily to be conceived of within the protection scope of the embodiments of the disclosure by those skilled in the art, and fall with the protection scope of the present disclosure. Therefore, the protection scope of the embodiments of the disclosure is defined by the claims.

What is claimed is:

1. A method for forming a semiconductor structure, comprising:
providing a substrate, at least a gate structure, a first dielectric layer covering a surface of the substrate and covering the gate structure being provided on the substrate, a first dielectric layer on a side surface of the gate structure serving as a first sidewall;
forming a sacrificial sidewall on a side surface of the first sidewall;
removing the sacrificial sidewall after a first doped region and a second doped region are respectively formed in the substrate on both sides of the sacrificial sidewall; and
forming a second sidewall on the side surface of the first sidewall.

2. The method of claim 1, further comprising:
forming third doped regions in the substrate on both sides of the first sidewall before the sacrificial sidewall is formed.

3. The method of claim 2, wherein the gate structure comprises a third barrier layer located on a top of the gate structure, a thickness of the first dielectric layer being 5% to 20% of a thickness of the third barrier layer.

4. The method of claim 3, wherein the first dielectric layer comprises one of or any combination of silicon nitride, silicon oxynitride or silicon carbonitride.

5. The method of claim 3, wherein forming the third doped regions in the substrate on both sides of the first sidewall comprises:
performing a second ion implantation process on the substrate on both sides of the first sidewall by taking the first sidewall and the gate structure as a mask to form the third doped regions,
wherein an implantation energy of the second ion implantation process is 2 KeV to 120 KeV, and a junction depth of the third doped regions is 5 nm to 50 nm.

6. The method of claim 1, wherein a dimension of the sacrificial sidewall in a first direction is greater than a dimension of the second sidewall in the first direction, the first direction is an arrangement direction of the first sidewall and the sacrificial sidewall, and the first direction is parallel to the surface of the substrate.

7. The method of claim 1, wherein forming the first doped region and the second doped region in the substrate on both sides of the sacrificial sidewall comprises:
performing a first ion implantation process on the substrate on both sides of the sacrificial sidewall by taking the gate structure, the first sidewall and the sacrificial sidewall as a mask to form the first doped region and the second doped region.

8. The method of claim 1, wherein forming the second sidewall on the side surface of the first sidewall comprises:
the second sidewall comprising a first sub-sidewall and a second sub-sidewall;
forming an initial first insulating layer covering the first dielectric layer, removing part of the initial first insulating layer, and retaining the initial first insulating layer located on the side surface of the first sidewall to form the first sub-sidewall; and
forming an initial second insulating layer covering the first dielectric layer and the first sub-sidewall, removing part of the initial second insulating layer, and retaining the initial second insulating layer located on a side surface of the first sub-sidewall to form the second sub-sidewall, so as to form the second sidewall.

9. The method of claim 8, wherein the first sub-sidewall and/or the second sub-sidewall comprises multiple layers.

10. The method of claim 1, wherein at least a first gate structure and a second gate structure which are adjacent with each other are formed on the substrate, the first doped region is formed between the first gate structure and the second gate structure, and the second doped regions are formed on both sides of the first gate structure and the second gate structure, respectively.

11. A semiconductor structure, comprising:
a substrate;
a gate structure located on the substrate;
a first dielectric layer covering a surface of the gate structure and part of a surface of the substrate, the first dielectric layer comprising a first sidewall located on a side surface of the gate structure;
a second sidewall located at a side surface of the first sidewall; and
a first doped region and a second doped region, respectively located on both sides of the second sidewall of the gate structure, the first doped region and the second doped region respectively having a first distance from the second sidewall.

12. The semiconductor structure of claim 11, further comprising:
third doped regions located in the substrate on both sides of the first sidewall and partially overlapping the second sidewall.

13. The semiconductor structure of claim 11, wherein the gate structure comprises a third barrier layer located on a top of the gate structure, and a thickness of the first dielectric layer is 5% to 20% of a thickness of the third barrier layer.

14. The semiconductor structure of claim 13, wherein the first dielectric layer comprises one of or any combination of silicon nitride, silicon oxynitride or silicon carbonitride.

15. The semiconductor structure of claim 13, wherein the gate structure further comprises a first conductive layer, a first barrier layer, a second conductive layer, a second barrier layer and a gate dielectric layer arranged in sequence from top to bottom.

16. The semiconductor structure of claim 15, wherein the gate dielectric layer comprises a high-K material layer.

17. The semiconductor structure of claim 15, wherein the first barrier layer comprises a barrier material layer doped with silicon.

18. The semiconductor structure of claim 17, wherein the first conductive layer comprises a metal material, and the second conductive layer comprises polysilicon.

19. The semiconductor structure of claim 11, wherein the gate structure comprises a first gate structure and a second gate structure, the first doped region is located between the first gate structure and the second gate structure, and the second doped regions are located on both sides of the first gate structure and the second gate structure, respectively.
